(19) United States
(12) Patent Application Publication
(10) Pub. No.: US 2014/0360710 A1
(43) Pub. Date: Dec. 11, 2014

(54) HEAT-DISSIPATING ASSEMBLY FOR ELECTRONIC COMPONENT

(71) Applicant: DELTA ELECTRONICS POWER (DONG GUAN) CO., LTD., Dongguan City (CN)

(72) Inventor: Weiguo LI, DONGGUAN CITY (CN)

(21) Appl. No.: 14/299,688

(22) Filed: Jun. 9, 2014

(30) Foreign Application Priority Data
Jun. 8, 2013 (CN) 201310228770.7

(51) Int. Cl. H05K 7/20

(52) U.S. Cl. CPC H05K 7/2039
USPC 165/185

(57) ABSTRACT

A heat-dissipating assembly for electronic component is provided, which comprises a body and at least one insert element. The body has a front surface and a back surface opposite to each other, two side surfaces opposite to each other, and at least one through-hole which penetrates the two side surfaces. Each of the insert elements is detachably inserted into the at least one through-hole respectively, and is provided with at least one internal thread hole which is formed from the front surface to the back surface of the body. The heat-dissipating assembly for electronic component according to the present disclosure may be used easily and flexibly, benefits in reducing space to be occupied.

### CROSS-REFERENCE TO RELATED APPLICATIONS

This application claims benefits of Chinese Patent Application No. 201310228770.7, filed on Jun. 8, 2013 in the State Intellectual Property Office of China, the disclosure of which is incorporated herein by reference in its entirety.

### TECHNICAL FIELD

The present disclosure relates in general to a heat-dissipating device, in particular, to a heat-dissipating assembly of electronic components for dissipating the heat from electronic components.

### BACKGROUND

Generally, large amount of heat generated from electronic components during operation is dispersed by heat-dissipating device. In particular, the heat-dissipating device mounted to the electronic components can dissipate the heat generated from electronic components.

The conventional heat-dissipating device for electronic components comprises a body which is in the form of a metal plate. The electronic components are installed on the heat-dissipating device by screws or their combinations with nuts.

As shown in FIGS. 1A and 1B, the conventional heat-dissipating device having internal thread comprises a body 1 which is in the form of a metal plate and has a plurality of internal thread hole 11 run through the body of the heat-dissipating device 1 from back to front surface. During the installation of an electronic component 10 on the heat-dissipating device, the screw 2 goes through one electronic component 10 and mates its external thread with the internal thread of the hole 11 of the body 1. The heat-dissipating device has advantages of cost-saving and space-saving since the nut is not necessary in the installation. However, the heat-dissipating device having internal thread is in the form of a thin metal plate in which the length of the internal thread holes 11 is relatively short, therefore, in this case only one electronic component is capable to be mounted at the front or back surface of the heat-dissipating device by one internal thread hole 11, and it is difficult to install two electronic components at both surfaces of the heat-dissipating device in a locking manner.

As shown in FIGS. 2A, 2B and 2C, the conventional heat-dissipating device having internal mounting holes comprises a body 1 which is in the form of a metal plate. A plurality of mounting holes 12 run through the body 1 of the heat-dissipating device from back to front. When installing one electronic component 10 to the heat-dissipating device by one mounting hole 12, the screw 2 goes through the electronic component 10, crosses the mounting hole 12 from the front of the body 1, and is engaged with a nut 3 at the back of the body 1. When installing two electronic components 10 to the heat-dissipating device by one mounting hole 12, screw 2 goes through one electronic component 10, crosses the mounting hole 12 from the front of the body 1, then goes through the other electronic component 10, and subsequently is engaged with a nut 3 at the back of the body 1. The heat-dissipating device with internal mounting holes allow the installation of two electronic components 10 at both surfaces of the body 1, that is, the screw 2 crosses the first electronic component 10, the mounting hole 12 and the second electronic component 10 sequentially, and then is screwed by the nut 3. In this case, however, the electronic component 10 may be mounted on one surface of the body 1 rather than both surfaces, the cost and the occupied space resulted from the nut is increased, which is adverse for the electronic apparatus with small size. Moreover, interference or short circuit is likely to occur between the nut 3 and other electronic components in electronic apparatus due to the limitation of the small size.

### SUMMARY

The present disclosure provides a heat-dissipating assembly for electronic component, which may achieve a flexible installation of electronic components along with a space-saving benefit.

Additional aspects and advantages will be set forth in part in the description which follows and, in part, will be apparent from the description, or may be learned by practice of the disclosure.

According to one aspect of the disclosure, a heat-dissipating assembly for electronic component is provided, which comprises a body having a front surface and a back surface opposite to each other, two side surfaces opposite to each other, and at least one through-hole which penetrates the two side surfaces; at least one insert element each of which is detachably inserted into the at least one through-hole respectively, and is provided with at least one internal thread hole which is formed from the front surface to the back surface of the body.

According to one embodiment of the present disclosure, wherein the body is provided with an aperture at the front surface or/and back surface, which is corresponding to the internal thread hole of the insert element.

According to one embodiment of the present disclosure, wherein the cross section of the through-hole is in a shape of rectangle.

According to one embodiment of the present disclosure, wherein the center line of the through-hole is in parallel with the bottom surface of the body.

According to one embodiment of the present disclosure, wherein the cross section of the insert element is in a shape of rectangle.

According to one embodiment of the present disclosure, wherein the insert element is fit with the through-hole, the insert element engages with the through-hole in clearance fit.

According to one embodiment of the present disclosure, wherein the thickness of the body is 3 mm-6 mm.

According to one embodiment of the present disclosure, wherein the body is made of aluminum, copper or iron.

According to one embodiment of the present disclosure, wherein the length of the insert element is equal to the width of the body.

According to one embodiment of the present disclosure, wherein the heat-dissipating assembly for electronic component further comprises at least one screw which may engage with at least one internal thread holes respectively.

According to one embodiment of the present disclosure, wherein the heat-dissipating assembly for electronic component further comprises at least one nut which may engage with at least one screw respectively.

### BRIEF DESCRIPTION OF THE DRAWINGS

The present disclosure will become more fully understood from the detailed description given hereinafter and the accompanying drawings which are given by way of illustration only, and thus are not limitative of the present disclosure

FIG. 1A illustrates a perspective schematic view of a first embodiment of conventional heat-dissipating device for electronic component;

FIG. 1B illustrates a cross section view of a first embodiment of conventional heat-dissipating device for electronic component;

FIG. 2A illustrates a perspective schematic view of a second embodiment of conventional heat-dissipating device for electronic component;

FIG. 2B illustrates a cross section view of a second embodiment of conventional heat-dissipating device for electronic component;

FIG. 2C illustrates a cross section view of a second embodiment of conventional heat-dissipating device for electronic component, in which an electronic component is mounted on one of the front and back surfaces;

FIG. 3A illustrates an exploded view of the heat-dissipating assembly for electronic component according to the present disclosure;

FIG. 3B illustrates cross section view along line A-A in FIG. 3A;

FIG. 3C illustrates a cross section view along line B-B in FIG. 3A, in which an electronic component is mounted on one of the front and back surfaces;

FIG. 3D illustrates a cross section view along line B-B in FIG. 3A, in which electronic components are mounted on both surfaces of the body;

FIG. 3E illustrates a perspective schematic view of the heat-dissipating assembly for electronic component according to the present disclosure, in which electronic components are mounted on both surfaces of the body; and

FIG. 3F illustrates a top view of FIG. 3E.

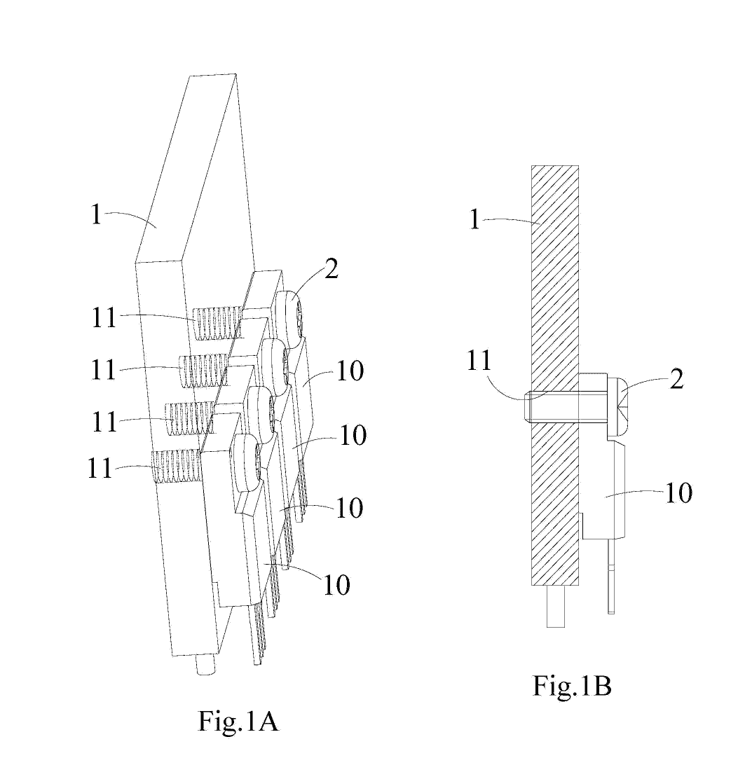

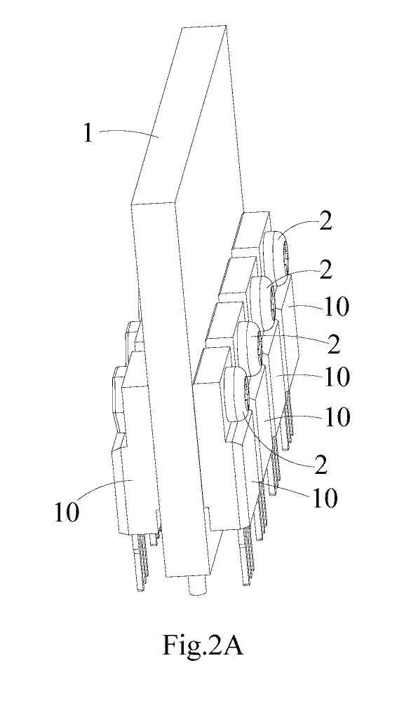

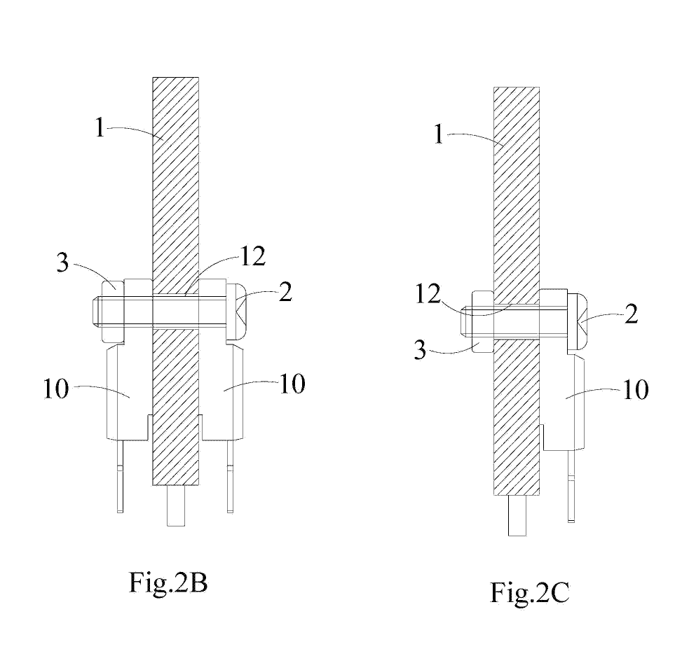

### DETAILED DESCRIPTION

Exemplary embodiments of the present disclosure are described more fully hereinafter with reference to the accompanying drawings. The present disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. In the drawings, the size and relative sizes of layers and regions may be exaggerated for clarity.

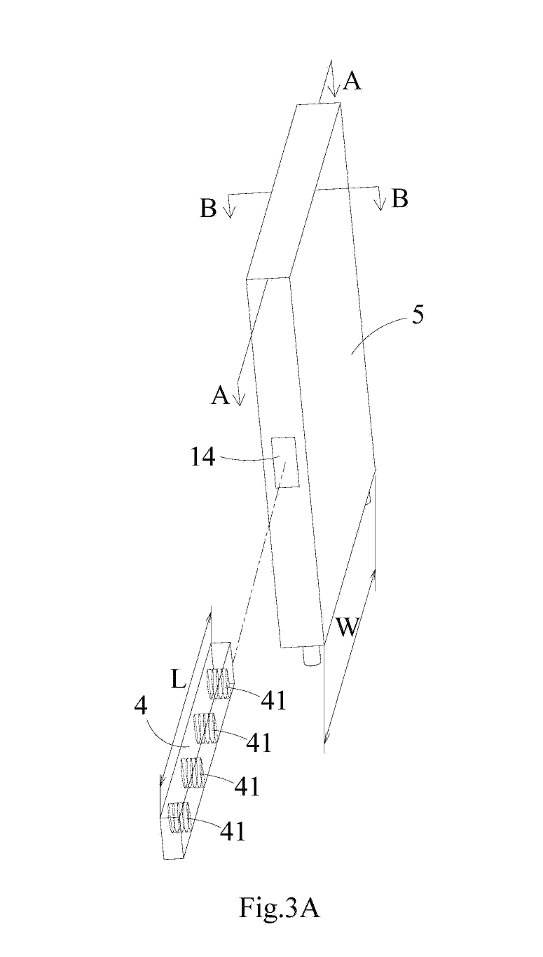

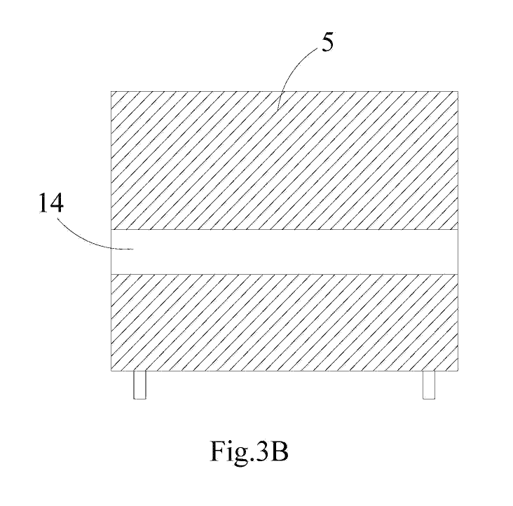

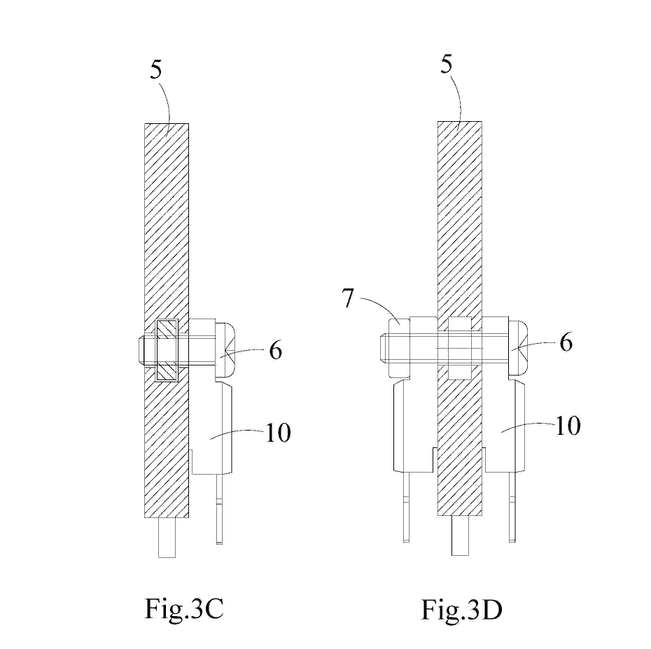

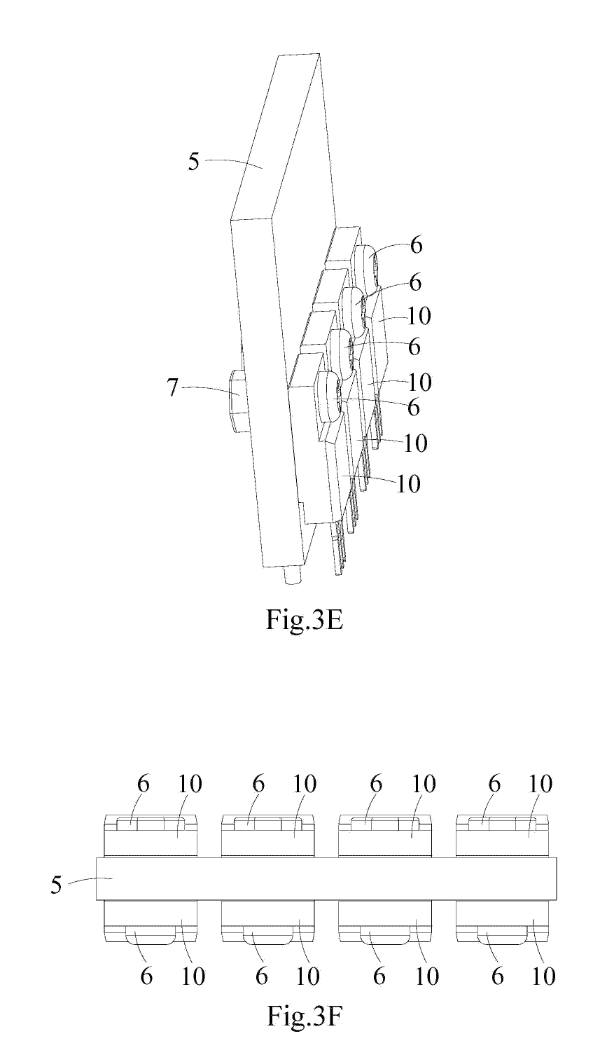

Referring to FIGS. 3A to 3F, the heat-dissipating assembly for electronic component according to the present disclosure comprises a body 5 and an insert element 4.

The body 5 may be a metal plate made of metallic materials such as aluminum, copper or iron. The body 5 may be in a shape of cuboid, which has a front surface, a back surface, a top surface, a bottom surface and two side surfaces. The thickness of the body 5 is not particularly limited, and may be about 3 mm to 6 mm. As for other heat-dissipating devices, the thickness of the body 5 may be even larger or smaller.

The body 5 comprises a through-hole 14 which perforates the two side surfaces of the body 5. The shape of the cross section of the through hole 14 may be various, such as rectangle. The number of the through-hole 14 may be one or more than one.

The insert element 4 has a shape coincident with that of the through-hole 14, and can be inserted into the through-hole 14 detachably. When plugging into the through-hole 14, the insert element 4 engages with the through-hole 14 in a clearance fit, for example, in a clearance fit of 0.5 mm to 1.5 mm, so as to realize a pluggable connection between the insert element 4 and body 5, and ensure a not easy separation of the insert element 4 from the through-hole 14. The length L of the insert element 4 is equal or unequal to the width W of the body 5. The number of the insert element 4 may be one or more than one.

Four internal thread holes 41 are provided in each insert element 4. The number of the internal thread holes may be determined depending on the number of the electronic components 10 to be mounted, which is not limited to four. The internal thread holes 41 are provided along frond and back of the body 5 with two openings at both ends towards the body 5. Two apertures are provided at both front surface and back surface of the body 5 directly towards the internal thread holes 41. The center line of the aperture is collinear with the center line of the internal thread hole 41. The electronic component 10 is mounted to the body 1 by a screw passing through the two apertures and internal thread hole 41. In case that the center line of the through-hole 14 in the body 5 is in parallel with the bottom surface of the body 5, the insert element 4 is also in parallel with the bottom surface of the body 5, such that all electronic components 10 mounted to the body 5 are in the same level, which bring out an aesthetic appearance, and benefits the arrangement for the electronic components 10 to the body 5.

The heat-dissipating assembly for electronic component according to the present disclosure further comprises at least one screw 6 engaging with at least one internal thread holes 41 of the insert element 4 respectively. Furthermore, the heat-dissipating assembly for electronic component comprises at least one nut 7 engaging with at least one screw 6 respectively.

Referring to FIG. 3C, by the heat-dissipating assembly for electronic component according to the present disclosure, in case that an electronic component 10 is required to be mounted to one surface of the heat-dissipating assembly, e.g. the front or back surface, the insert element 4 be plugged into the through-hole 14 of the body 5 with the internal thread holes 41 fully aligned with the aperture of the body 5, the screw 6 passes through the electronic component 10 and the aperture of the body 5 at the front or back surface, and engages with the internal thread holes 41, in turn, go through the aperture of the body 5 at the back or front surface (which is not necessary), such that the electronic component 10 is mounted to the body 5 at the front or back surface.

Referring to FIGS. 3D, 3E and 3F, in case that electronic components 10 are required to be mounted to both front surface and back surface of the heat-dissipating assembly, the screw 6 passes through one electronic component 10, the apertures provided correspondingly at the front and back surface of the body 5, and the other electronic component 10 in sequence, and is screwed by the nut 7. Meanwhile, the insert element 4 is not needed to be plugged into the internal thread holes 41 of the body 5.

As described above, the heat-dissipating assembly for electronic component according to the present disclosure is able to realize that electronic components 10 may be mounted to one surface of the body 5 without using nuts so as to save cost and area occupied by the nut; meanwhile, electronic components 10 may also be mounted to both surfaces of the body 5 at the same time. Therefore, the present disclosure may achieve all the effect of two kinds of heat-dissipating device in the prior art.

As described above, the heat-dissipating assembly for electronic component according to the present disclosure has many advantages. For example, as the heat-dissipating assembly comprises a body and an insert element detachably connected with the body, the installation can be achieved by an insert element with thread when an electronic component is tended to be mounted to one surface of the body, thus the cost and the space occupied by nut be reduced. When electronic components are required to be mounted to both surfaces of the body, the insert element is pulled out, and the installation is achieved via the engagement between a screw and nut. Therefore, the heat-dissipating assembly for electronic component according to the present disclosure may be used easily and flexibly, and has a benefit of space-saving and cost-saving.

It should be noted that the above embodiments are only illustrated for describing the technical solution of the disclosure and not restrictive, and although the embodiments are described in detail by referring to the aforesaid embodiments, the skilled in the art should understand that the aforesaid embodiments may be modified and portions of the technical features therein may be equally changed, which does not depart from the spirit and scope of the technical solution of the embodiments of the disclosure.

What is claimed is:

1. A heat-dissipating assembly for electronic component, comprising:
a body (5) having a front surface and a back surface opposite to each other, two side surfaces opposite to each other, and at least one through-hole (14) which penetrates the two side surfaces;
at least one insert element (4) each of which is detachably inserted into the at least one through-hole (14) respectively, and is provided with at least one internal thread hole (41) which is formed from the front surface to the back surface of the body (5).

2. The heat-dissipating assembly for electronic component of claim 1, wherein the body (5) is provided with an aperture at the front surface or/and back surface, which is corresponding to the internal thread hole (41) of the insert element (4).

3. The heat-dissipating assembly for electronic component of claim 1, wherein the cross section of the through-hole (14) is in a shape of rectangle.

4. The heat-dissipating assembly for electronic component of claim 1, wherein the center line of the through-hole (14) is in parallel with the bottom surface of the body (5).

5. The heat-dissipating assembly for electronic component of claim 4, wherein the cross section of the insert element (4) is in a shape of rectangle.

6. The heat-dissipating assembly for electronic component of claim 1, wherein the insert element (4) is fit with the through-hole (14), the insert element (4) engages with the through-hole (14) in clearance fit.

7. The heat-dissipating assembly for electronic component of claim 1, wherein the thickness of the body (5) is 3 mm-6 mm.

8. The heat-dissipating assembly for electronic component of claim 1, wherein the body (5) is made of aluminum, copper or iron.

9. The heat-dissipating assembly for electronic component of claim 1, wherein the length (L) of the insert element (4) is equal to the width (W) of the body (5).

10. The heat-dissipating assembly for electronic component of claim 1, wherein the heat-dissipating assembly for electronic component further comprises at least one screw (6) which may engage with at least one internal thread holes (41) respectively.

11. The heat-dissipating assembly for electronic component of claim 10, wherein the heat-dissipating assembly for electronic component further comprises at least one nut (7) which may engage with at least one screw (6) respectively.
